(19) United States
(12) Patent Application Publication
(10) Pub. No.: US 2006/0175606 A1
(43) Pub. Date: Aug. 10, 2006

(54) Subthreshold design methodology for ultra-low power systems

(76) Inventors: Alice Wang, Richardson, TX (US); Anantha Chandrakasan, Belmont, MA (US)

Correspondence Address: Hayes Soloway PC;4th Floor, 175 Canal Street, Manchester, NH, 03101, US

(21) Appl. No.: 11/051,924

(22) Filed: Feb. 4, 2005

(51) Int. Cl. H01L 21/66; H01L 21/00; H01L 23/58

(52) U.S. Cl. 257/48; 438/305; 438/17; 438/48

(57) ABSTRACT

A system and method for enabling a device to function at a subthreshold voltage level of the device is provided. Generally, the system contains a subthreshold data memory capable of functioning when a supply voltage is within the subthreshold voltage level of the device. The system also contains control logic and a read only memory capable of functioning when the supply voltage is within the subthreshold voltage level of the device.

### FIELD OF THE INVENTION

The present invention is generally related to microchip fabrication, and more particularly is related to a subthreshold design methodology for ultra-low power systems.

### BACKGROUND OF THE INVENTION

With advancement of technology, device miniaturization is becoming more and more prevalent. With such miniaturization, providing power to such devices for elongated periods of time is a challenge. As an example, energy efficient digital signal processors (DSPs) are becoming increasingly important with the growth of portable, wireless, battery-operated appliances such as cellular phones, Personal Digital Assistants (PDAs), and laptops.

One environment that uses energy efficient DSPs is wireless sensor networks. A wireless sensor network is a gathering of a large number of distributed microsensor nodes. The nodes gather sensing information from the environment and transmit event occurrences through a wireless network to a remote end-user. Networked microsensor nodes enable a variety of applications such as, but not limited to, warehouse inventory tracking, location sensing, machine-mounted sensing, patient monitoring, and building climate control.

Due to size of the distributed microsensor nodes, it is infeasible to replace batteries of the distributed sensors. Therefore, each microsensor node scavenges for energy from the environment to achieve long system lifetimes required by the application for which the microsensor is applied. In addition to the above-mentioned, the effects of process variations known to exist in logic, which are associated with manufacturing of the logic, are known to be amplified when voltage supplied to the logic is extremely low. As an example, the effects of process variations known to exist in memory bit cells, which are associated with manufacturing of the memory bit cells, are known to be amplified when voltage supplied to the memory bit cells is extremely low. These memory bit cells are located in microsensor nodes and other devices.

Many different technologies have been used to attempt to provide power to such devices. As an example, attempts have been made to provide power by converting energy from solar sources, thermal gradients, radio frequency, and via use of mechanical vibration. While these technologies have been successful in providing power to certain devices, devices having extremely low power requirements, which may be portable, require a power source that is very small. Alternatively, a manner of preserving power for an elongated period of time is required.

Thus, a heretofore unaddressed need exists in the industry to address the aforementioned deficiencies and inadequacies.

### SUMMARY OF THE INVENTION

Embodiments of the present invention provide a system and method capable of enabling a device to function at a subthreshold voltage level of said device. Briefly described, in architecture, one embodiment of the system, among others, can be implemented as follows. The system contains a subthreshold data memory capable of functioning when a supply voltage is within the subthreshold voltage level of the device. The system also contains control logic and a read only memory capable of functioning when the supply voltage is within the subthreshold voltage level of the device.

The present invention can also be viewed as providing a method for determining an optimal operating point of a device, where the optimal operating point is within a subthreshold voltage level of the device. In this regard, one embodiment of such a method, among others, can be broadly summarized by the following steps: determining switching energy of the device; determining leakage energy of the device; combining the switching energy and the leakage energy, resulting in a combined energy; plotting the combined energy for different supply voltage and/or threshold voltage values, resulting in a contour; and determining a lowest point on the contour to derive the optimal operating point of the device.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a block diagram illustrating an example of a wireless microsensor in which the present subthreshold FFT processor may be provided.

FIG. 2 is a block diagram further illustrating the subthreshold FFT processor, in accordance with the first exemplary embodiment of the invention.

FIG. 3 is a schematic diagram further illustrating the data memory of FIG. 2.

FIG. 4 is a schematic diagram further illustrating an example of CMOS logic that may be provided within the write portion of the data memory.

FIG. 5 is a schematic diagram further illustrating an example of CMOS logic that may be provided within the read portion of the data memory.

FIG. 6 is a schematic diagram further illustrating a multiplexer of the read portion.

FIG. 7 is a schematic diagram further illustrating the butterfly data path of FIG. 2.

FIG. 8 is a schematic diagram illustrating an example of the butterfly data path of FIG. 7.

FIG. 9 is a flowchart illustrating a method of determining an optimal operating point, being a subthreshold voltage, of the wireless microsensor of FIG. 1, in which the subthreshold FFT processor is located.

### DETAILED DESCRIPTION

The present system and method provides an energy aware architecture and subthreshold circuits embodied as a subthreshold Fast Fourier Transform (FFT) processor. For exemplary purposes, the subthreshold FFT processor is described as being located within a wireless microsensor. While the present detailed description discloses use of the present subthreshold FFT processor in a wireless microsensor, one having ordinary skill in the art would appreciate that the subthreshold FFT processor may be used in a different semiconductor environment. As an example, the subthreshold FFT processor may be used within different portable, wireless, battery-operated applications such as cellular phones, personal data assistants (PDAs), and laptops. Specifically, since FFT is a signal processing function that is common to a variety of microsensor applications for extracting frequency information from microsensor signals, which is then used for target tracking, localization, or compression, the present subthreshold FFT processor may be provided within the wireless microsensor.

In addition to the abovementioned, the present processor need not be an FFT processor. In fact, the structure and functionality described herein may be provided as a processor that does not provide FFT calculations. As such, the present description of a subthreshold FFT processor is merely provided for exemplary purposes. Alternative embodiments of the present subthreshold FFT processor are described herein.

It should be noted that the following described design of the subthreshold FFT processor allows a wireless microsensor using the subthreshold FFT processor to function at a voltage level that is below the threshold voltage level of the wireless microsensor; otherwise referred to herein as a subthreshold voltage level. By functioning below this threshold voltage level, the subthreshold FFT processor is capable of enabling the wireless microsensor to function for elongated periods of time on minimal energy. In addition, it is ideal to determine an optimal operating point, having a subthreshold voltage, and to operate at this optimal operating point.

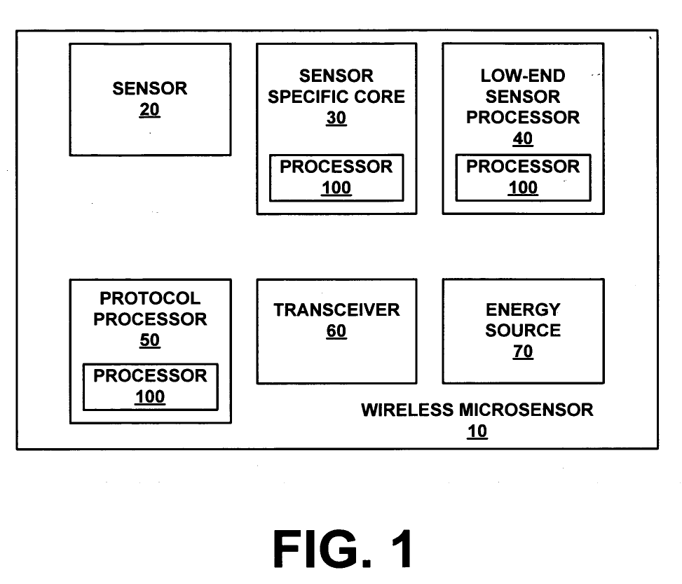

FIG. 1 is a block diagram illustrating an example of a wireless microsensor 10 in which the present subthreshold FFT processor 100 may be provided. It should be noted that while the following describes a subthreshold FFT processor 100 as being located within each different digital logic device within the wireless microsensor 10, logic provided within a subthreshold FFT processor 100 may instead be provided throughout the wireless microsensor 10, as a single integrated circuit, having each digital logic device connected thereto. Specifically, digital logic within the wireless microsensor 10 may contain or connect to the subthreshold FFT processor 100 for purposes of scaling the digital logic supply voltage to below the digital logic threshold voltage.

As is shown by FIG. 1, the wireless microsensor 10 contains a sensor 20 used to sense environmental elements associated with the purpose of the wireless microsensor 10. As an example, if the wireless microsensor 10 is being used in the health industry, the sensor 20 may be used to monitor a heartbeat. The wireless microsensor 10 also contains a sensor specific core 30, which contains logic hard wired and configured to perform a single function associated with the purpose of the wireless microsensor 10. As an example, the sensor specific core 30 may be wired and configured only to perform FFT calculations.

A low-end sensor processor 40 is also provided within the wireless microsensor 10. The low-end sensor processor 40 is provided within the wireless microsensor 10 for performing functions associated with the purpose of the wireless microsensor 10, however, unlike the sensor specific core 30, functions performed by the low-end sensor processor 40 are provided via software. Therefore, the low-end sensor processor 40 is capable of performing many different functions as prescribed by software (not shown), while the sensor specific core 30 is capable of a specific function.

The wireless microsensor 10 also contains a protocol processor 50 that is capable of providing functionality associated with providing wireless communication capabilities of the wireless microsensor 10. As an example, the protocol processor 50 may be used in providing a Media Access Control (MAC) address of the wireless microsensor 10 or for other wireless communication purposes. A radio frequency (RF) transceiver 60 may also be provided within the wireless microsensor 10 for enabling wireless communication. In addition to the above-mentioned, the wireless microsensor 10 may also contain an energy source 70 for providing energy (i.e., a voltage) to the sensor 20, the sensor specific core 30, the low-end sensor processor 40, the protocol processor 50, and the RF transceiver 60.

As has been mentioned above, each portion of the wireless microsensor 10 containing digital logic may contain a processor similar to the subthreshold FFT processor 100. It should be noted, however, that due to the requirement of performing FFT calculations, the subthreshold FFT processor 100 may be located within the sensor specific core 30 if it is in fact wired and configured only to perform FFT calculations. Alternatively, since the low-end sensor processor 40 and the protocol processor 50 do not perform FFT calculations, the low-end sensor processor 40 and the protocol processor 50 may contain subthreshold processors that contain logic similar to the subthreshold FFT processor 100, yet without logic that is capable of performing FFT calculations. Use of a subthreshold processor that does not perform FFT calculations is described in detail herein.

By containing either, the subthreshold FFT processor 100, or a subthreshold processor not having FFT logic of the subthreshold FFT processor 100, logical devices containing one of the processors are capable of functioning at supply voltages below the minimum energy point of the logical device. Further description of the subthreshold FFT processor 100, specifically, structure and functionality, is provided herein.

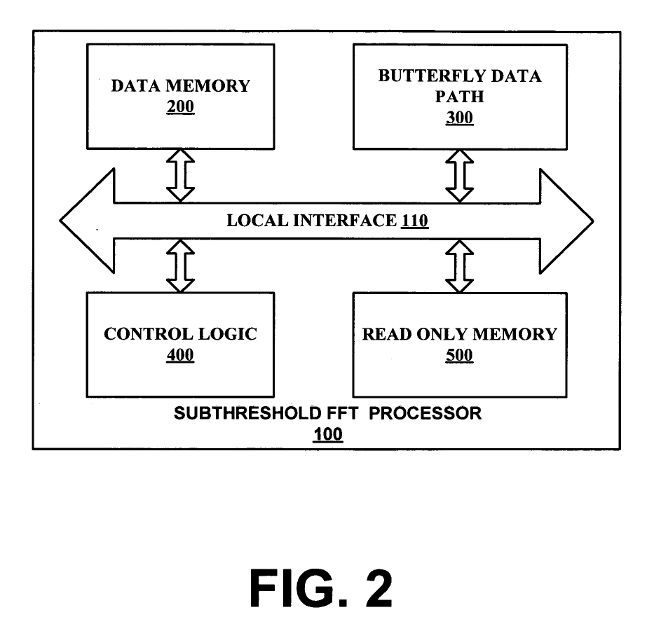

FIG. 2 is a block diagram further illustrating the subthreshold FFT processor 100, in accordance with the first exemplary embodiment of the invention. As is shown by FIG. 2, the subthreshold FFT processor 100 contains a data memory 200, a butterfly data path 300, control logic 400, and a read only memory 500, each of which is connected via a local interface 110. The local interface 110 can be, for example but not limited to, one or more buses or other wired or wireless connections, as is known in the art. The local interface 110 may have additional elements, which are omitted for simplicity, such as controllers, buffers (caches), drivers, repeaters, and receivers, to enable communication. Further, the local interface 110 may include address, control, and/or data connections to enable appropriate communication among the aforementioned components. The combination of the present data memory 200, butterfly data path 300, control logic 400, and read only memory 500 is utilized to provide an energy-aware architecture, as is explained in detail below.

Data Memory

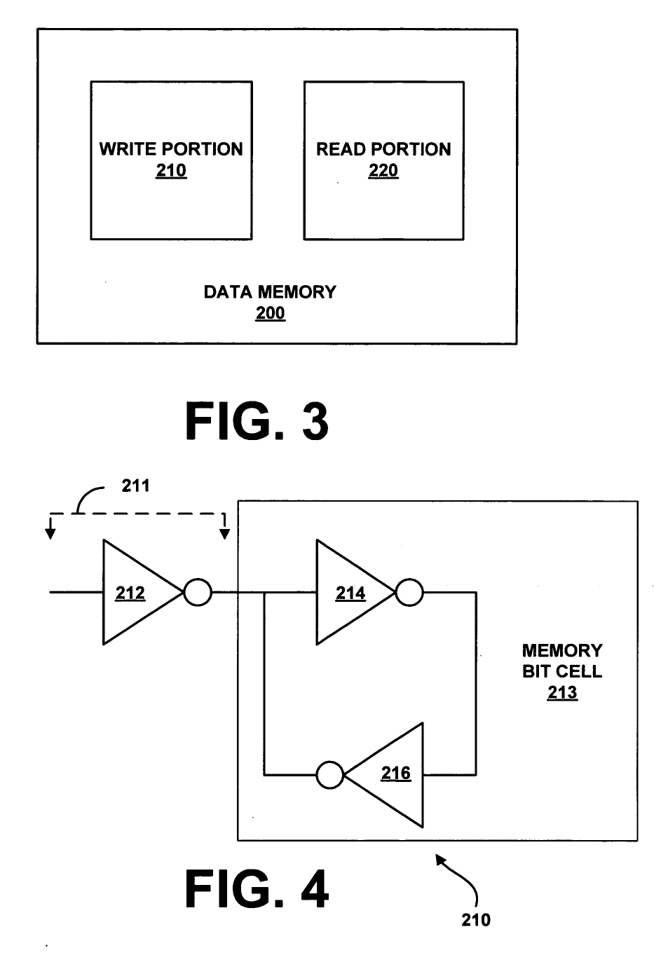

FIG. 3 is a schematic diagram further illustrating the data memory 200 of FIG. 2. The data memory 200 is used to store data associated with functionality of the circuit having the present subthreshold FFT processor 100 therein, regardless of the decrease in voltage to the data memory 200. In addition, the data memory 200 stores results of FFT calculations that are performed by the present subthreshold FFT processor 100 in accordance with the first exemplary embodiment of the invention. Specifically, the design of the data memory 200, as explained in detail below, allows the data memory 200 to store data therein regardless of process variations of memory bit cells within the data memory 200, that would otherwise not function properly (i.e., continue storing data) at very low voltage levels. It should be noted that due to the data memory being capable of functioning at subthreshold voltage levels, the data memory is also referred to herein as a subthreshold data memory.

The data memory 200 preferably uses complementary metal oxide semiconductor (CMOS) logic. As is known by those having ordinary skill in the art, CMOS semiconductors use both negative-channel metal-oxide semiconductor (NMOS) and positive-channel metal-oxide semiconductor (PMOS) circuits. Since only one of the circuit types is on at any given time, CMOS logic requires less power than logic using just one type of transistor.

As is shown by FIG. 3, the data memory 200 contains a write portion 210 and a read portion 220. The write portion 210 of the data memory 200 uses CMOS logic to provide a memory cell feedback loop, thereby breaking feedback known to be associated with writing to a memory cell.

FIG. 4 is a schematic diagram further illustrating an example of CMOS logic that may be provided within the write portion 210 of the data memory 200. As is shown by FIG. 4, the write portion 210, otherwise referred to herein as the memory feedback loop, contains at least one bit line 211, having a first feedback inverter 212 and a memory bit cell 213, where the memory bit cell 213 contains an inverter 214 and a second feedback inverter 216 therein. As mentioned above, both the inverter 214 and the second feedback inverter 216 are located within the memory bit cell 213.

When voltage levels below the threshold voltage level of the memory bit cell 213 are provided to the memory bit cell 213, the first feedback inverter 212 is not able to overcome memory bit cell feedback to write to the memory bit cell 213. The second feedback inverter 216 breaks feedback from the memory bit cell 213. Specifically, the second feedback inverter 216 is tri-stated within the data memory 200. This process is further described hereafter.

When the second feedback inverter 216 is driven, feedback received by the second feedback inverter 216 is routed back to the inverter 214 and fed back to the memory bit cell 213. Breaking the feedback from the memory bit cell 213 allows writing to the data memory 200 at subthreshold voltage levels. The second feedback inverter 216 is driven when not writing to the memory bit cell 213 and not driven when writing to the memory bit cell 213. Alternatively, the first feedback inverter 212 is driven when writing to the data memory 200 and not driven when not writing to the data memory 200. It should be noted that the feedback inverters 212, 216 may be a tri-state inverters.

The read portion 220 of the data memory 200 also uses CMOS logic to segment a read bit line into a hierarchical read bit line having multiple smaller parts that will function at low voltages. By segmenting the read bit line into multiple smaller parts, negative effects of process variations associated with each memory bit cell, such as, but not limited to, bit line leakage, are minimized. In addition, parallel leakage for each stage of the hierarchy is mitigated. Since these negative effects are known to those having ordinary skill in the art, further elaboration as to the process variations is not provided herein. In addition, these negative effects are described in further detail herein.

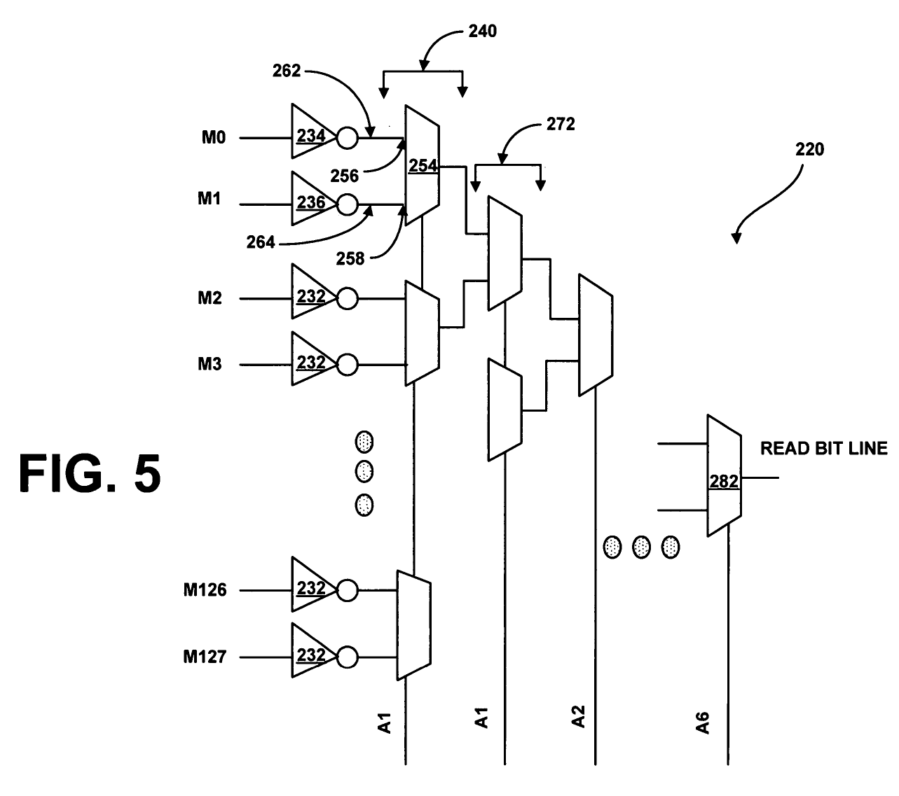

FIG. 5 is a schematic diagram further illustrating an example of CMOS logic that may be provided within the read portion 220 of the data memory 200. As is shown by FIG. 5, the read portion 220 of the data memory 200 contains a series of stages. An output of each memory bit cell M0-M127 is connected to an individual inverter 232, 234, 236, where an output of each inverter 232, 234, 236 connects to a first stage 240 of the read portion 220. As is known by those having ordinary skill in the art, inverters are capable of mitigating the effects of process variations in memory bit cells.

The first stage 240 of the read portion 220 contains a first series of multiplexers. In accordance with the first exemplary embodiment of the invention, each multiplexer is connected to two memory bit cells via two inverters 232, 234, 236. As an example, a first multiplexer 254 has a first input 256 that is fed by a first input line 262, where the first input line 262 is connected to a first inverter 234 and a first memory bit cell M0. In addition, the first multiplexer 254 has a second input 258 that is fed by a second input line 264, where the second input line 264 is connected to a second inverter 236 and a second memory bit cell M1.

Alternatively, it should be noted that each multiplexer within the first stage 240 may instead be connected to more than two memory bit cells. As an example, each multiplexer may be connected to four memory bit cells, or eight memory bit cells.

A second stage 272 of the read portion 220 contains a second series of multiplexers. Each multiplexer with the second stage 272 of the read portion 220 contains two inputs, where each input is connected to one other multiplexer. In addition, depending on the number of stages of the read portion 220, an output of the multiplexer is an input to another multiplexer in a different stage. As is shown by FIG. 5, the series of stages within the read portion 220 of the data memory 200 ends in a single multiplexer 282, where an output of the single multiplexer 282 is a read bit line (RBL). Data read from the memory bit cell is transmitted to the RBL.

In accordance with the first exemplary embodiment of the invention, the number of stages within the read portion 220 is directly associated with the number of memory bit cells within the data memory 200 and the number of memory bit cells connected to each multiplexer within the first stage 240 of the read portion 220. Specifically, each stage of the read portion 220 is capable of receiving one bit of a memory address being selected for reading. As an example, if two memory bit cells are connected to each multiplexer within the first stage 240 of the read portion 220 and the third memory bit cell is to be read, the read portion 220 may have as few as two stages, where selection of the third memory bit cell is performed by the first stage 240 and the second stage 272 receiving a “1”.

The above arrangement of multiplexers (i.e., the series of stages) results in parallel leakage, stacked transistors, and sneak leakage effects at low voltage operation, as is explained briefly below. Specifically, parallel leakage occurs when the idle current of parallel devices reduces Iₒₙ/I_{off}. In addition, long stacks of transistors affect the functionality of logic gates. When stacked devices are conducting, the effective drive of each device is diminished (e.g., the drive current of two stacked devices is approximately halved). Also, the threshold voltage of a stacked device increases due to larger source-to-body voltages causing both drive and leakage currents to decrease. To address the above-mentioned, inputs and outputs to each multiplexer are buffered via use of inverters, thereby preventing parallel leakage, stacked transistors, and sneak leakage effects.

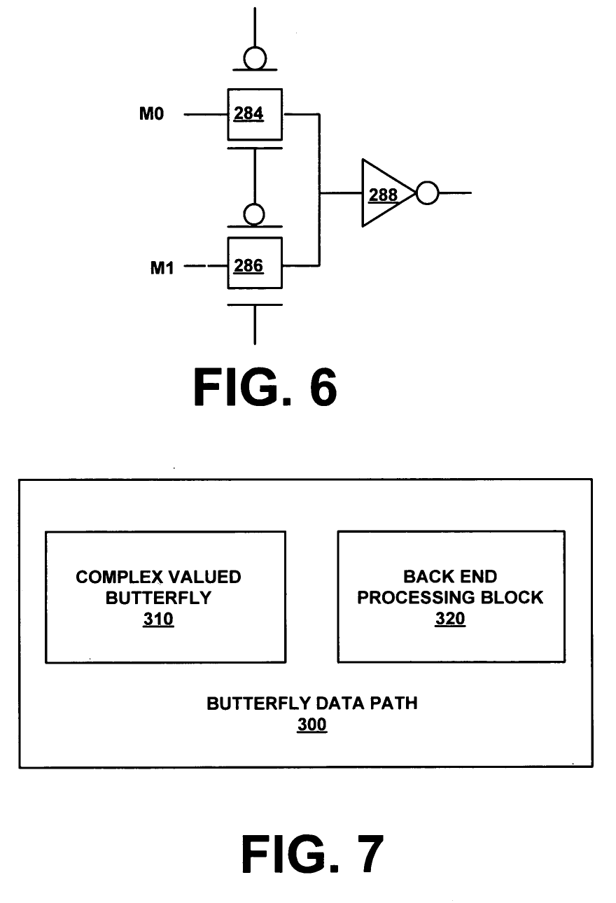

FIG. 6 is a schematic diagram further illustrating a multiplexer of the read portion 220. As is shown by FIG. 6, the multiplexer 282 contains a first transistor 284, a second transistor 286, and an inverter 288. Each of the transistors 284, 286 contains an input, an output, and is connected in series. The output of the transistors 284, 286 are connected to the inverter 288, thereby preventing parallel leakage, stacked transistors, and sneak leakage effects.

Read Only Memory

Returning to FIG. 2, the read only memory 500 is used by the subthreshold FFT processor 100 for storing data that is required to be permanently stored for execution of the FFT algorithm. As an example, twiddle factors may be stored within the read only memory 500. As is known by those having ordinary skill in the art, twiddle factors are used during the performance of FFT calculations to perform functions, such as, but not limited to, phase shifting.

As with the data memory 200, the design of the read only memory 500 allows the read only memory 500 data to be accessed therein regardless of process variations of memory bit cells within the read only memory 500, that would otherwise not function properly (i.e., read data properly) at very low voltages. In addition, as with the data memory 200, the read only memory 500 preferably uses CMOS logic. The structure of the read only memory 500 is the same as the read portion 220 of the data memory 200, which uses CMOS logic to segment a read bit line into a hierarchical read bit line having multiple smaller parts that will function at low voltages. Since the read only memory 500 contains the same structure as the read portion 220 of the data memory 200 further explanation of the read only memory 500 is not provided herein.

Butterfly Data Path

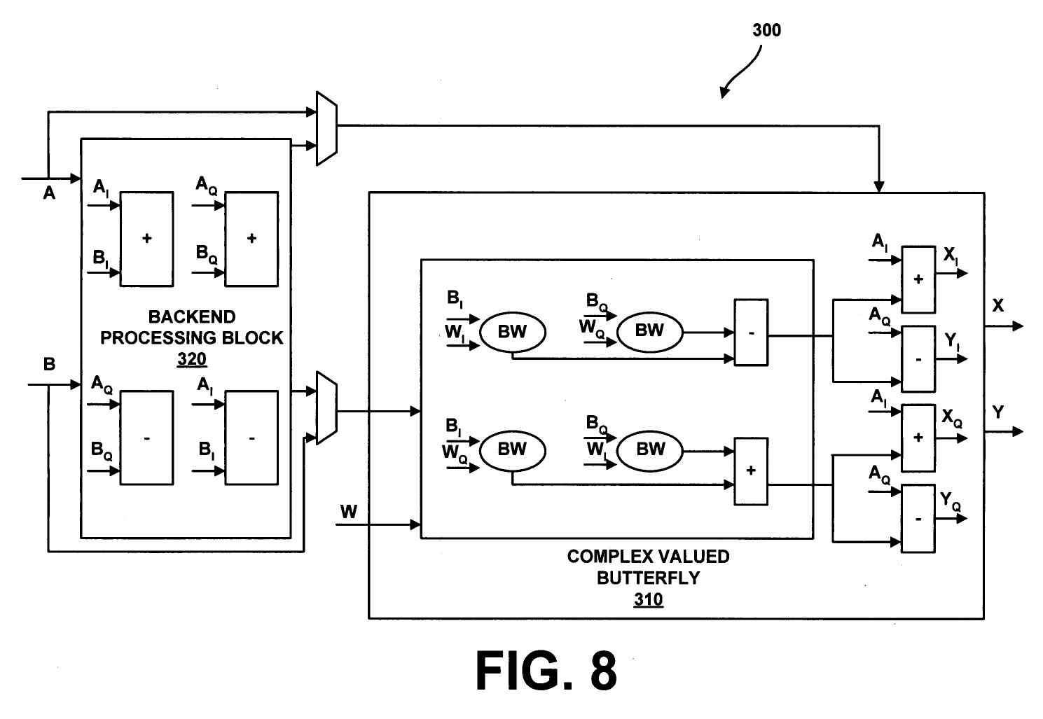

The butterfly data path 300 is located within the subthreshold FFT processor 100 specifically for providing FFT calculations within the subthreshold FFT processor 100. The butterfly data path 300 is fabricated from a subthreshold logic cell library. The butterfly data path 300 is designed by focusing on sizing for minimum supply voltage while factoring in the effects of process variations. FIG. 7 is a schematic diagram further illustrating the butterfly data path of FIG. 2. As is shown by FIG. 7, the butterfly data path 300 contains a complex valued butterfly 310 and a backend processing block 320. FIG. 8 is a schematic diagram illustrating an example of the butterfly data path 300 of FIG. 7.

The complex valued butterfly 310 is the main engine of the butterfly data path 300, which contains a complex valued multiplication followed by complex addition/subtraction. The main function performed by the complex valued butterfly 310 is summarized by the following equations.
X=A+B*W (Eq. 1)
Y=A−B*W (Eq. 2)
Within equations one and two, A, B, and W are complex inputs and X and Y are the complex outputs. This is performed for n stages of the 2ⁿ-pt. complex valued FFT (CVFFT) and for n-1 stages of the 2n-pt. butterfly data path.

The backend processing block 320 converts the CVFFT to real valued FFT (RVFFT). Specifically, in a last stage of the butterfly data path, inputs are fed into the backend processing block 320, which functions in accordance with the following equations.
A_{backend}=(Aᵢ+B_{I})+j(A_{Q}−B_{Q}) (Eq. 3)
B_{backend}=(A_{Q}+B_{Q})+j(A_{I}−B_{I}) (Eq. 4)
With equations three and four, A_{I} and A_{Q} represent the real and imaginary parts of complex value A, and B_{I} and B_{Q} represent the real and imaginary parts of complex value B. The backend processing block 320 is enabled for the last stage of computation by the butterfly data path 300.

In designing the subthreshold logic cell library both minimum energy point analysis as well as minimum supply voltage analysis is performed. The sizing methodology introduced during designing of the subthreshold logic cell library focuses on sizing for minimum supply voltage while factoring in the effects of process variations. It should be noted that this same sizing methodology may be used during designing of memory as well.

First, supply voltage to the subthreshold logic cell library is decreased until logic cells within the subthreshold logic cell library cease to function properly due to process variations. As an example, parallel leakage, stacked transistors, and/or sneak leakage may cause the logic cells to cease functioning properly.

Second, the logic cells that ceased to function properly due to process variations are modified to allow the logic cells to function properly at subthreshold voltage levels. Specifically, if the logic cells ceased functioning due to parallel leakage, the logic is redesigned to remove parallelism. Alternatively, if the logic cells ceased to function due to stacked transistors, the number of stacked transistors is limited in accordance with a selected subthreshold voltage level, basically by decreasing the number of stacked transistors until the logic cells function properly. In addition, if the logic cells ceased to function due to sneak leakage, inverters are added between cell boundaries (i.e., cell inputs and outputs).

It should be noted that if the subthreshold processor is not an FFT subthreshold processor, the data path located within the subthreshold processor may not be a butterfly data path. As an example, if the subthreshold processor were a matched filter subthreshold processor, the data path would instead be a filter data path, where the filter data path is hard coded to perform match filters.

Control Logic

The control logic 400 located within the data memory 200 is a finite state machine. Specifically, the control logic 400 is capable of controlling reading and writing to memory bit cells within the subthreshold FFT processor 100 in accordance with functionality of the wireless microsensor 10. In addition, the control logic 400 controls the location to which reading and writing is performed within the subthreshold FFT processor 100. Further, the control logic 400 controls when the subthreshold FFT processor 100 is initiated. Logic cells within the control logic 400 are created in the same manner as logic cells within the butterfly data path 300.

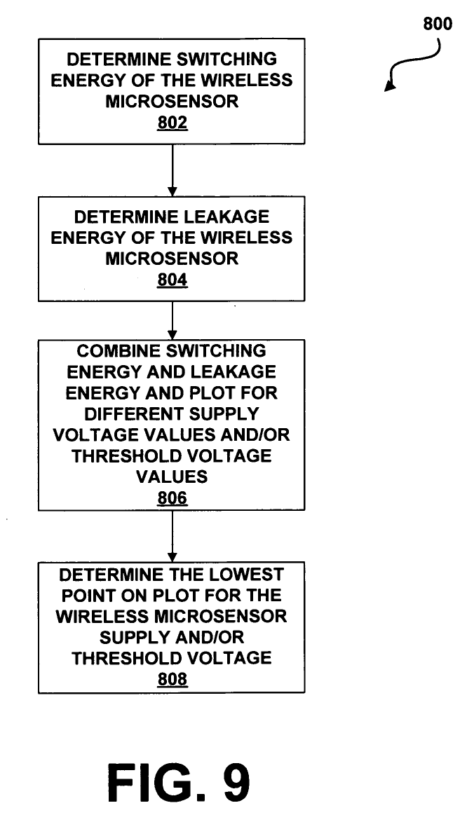

FIG. 9 is a flowchart 800 illustrating a method of determining an optimal operating point, being a subthreshold voltage, of the wireless microsensor 10 in which the subthreshold FFT processor 100 is located, in accordance with the first exemplary embodiment of the invention. It should be noted that any process descriptions or blocks in flowcharts should be understood as representing modules, segments, portions of code, or steps that include one or more instructions for implementing specific logical functions in the process, and alternate implementations are included within the scope of the present invention in which functions may be executed out of order from that shown or discussed, including substantially concurrently or in reverse order, depending on the functionality involved, as would be understood by those reasonably skilled in the art of the present invention.

The subthreshold FFT processor 100 is designed to operate at the optimal operating point that minimizes energy dissipation. Analysis of the energy and performance of the subthreshold FFT processor 100 shows that the minimum energy point occurs in the subthreshold region, where the supply voltage level is below the threshold voltage. Scaling the supply voltage (V_{DD}) below the threshold voltage (V_{TH}) limits the performance of CMOS circuits, but leads to orders of magnitude energy savings over nominal V_{DD} operation. The total energy of the subthreshold FFT processor 100 is broken down into switching energy and leakage energy.

As is shown by block 802, determination of the optimal operating point of the wireless microsensor 10 is first performed by determining switching energy of the wireless microsensor 10. The model for switching energy is given by the following equation.
E_{switching}=αNCV²_{DD} (Eq. 5)
In equation five, α is the activity factor, N is the number of clock cycles, C is the switched capacitance of the circuit, and V_{DD} is the supply voltage.

As is shown by block 804, the leakage energy is then calculated. The model for subthreshold leakage energy is given by the following equation.

$${E}_{leakage} = {V}_{DD} {I}_{S} exp ( \frac{{V}_{gs} - {V}_{th}}{{nV}_{T}} ) 1 - exp \frac{- {V}_{ds}}{( {V}_{T} )} T \qquad ( Eq . 6 )$$

In equation six, I_{S} is a technology dependent scaling parameter, V_{gs} is the gate-to-source voltage, V_{ds} is the drain-to-source voltage, Vₜₕ is the threshold voltage, V_{T} is the thermal voltage, S is the subthreshold slope, and T is the latency of computation. It should be noted that other sources of leakage energy may also be considered, as would be appreciated by one having ordinary skill in the art.

After determining the switching energy and the leakage energy, the switching energy and the leakage energy are combined (i.e., added) and plotted for different supply voltage (V_{DD}) and threshold voltage (V_{TH}) values (block 806). The plot of the combined energy for different supply voltage (V_{DD}) and threshold voltage (V_{TH}) values is a contour that may be observed for determining the minimum energy point of the wireless microsensor 10. Specifically, the lowest point on the plot is the minimum energy point of the wireless microsensor 10 and the optimal operating point.

It should be emphasized that the above-described embodiments of the present invention are merely possible examples of implementations, merely set forth for a clear understanding of the principles of the invention. Many variations and modifications may be made to the above-described embodiments of the invention without departing substantially from the spirit and principles of the invention. All such modifications and variations are intended to be included herein within the scope of this disclosure and the present invention and protected by the following claims.

What is claimed is:

1. A system capable of enabling a device to function at a subthreshold voltage level of said device, said system comprising:
a subthreshold data memory capable of functioning when a supply voltage is within said subthreshold voltage level of said device;
control logic; and
a read only memory capable of functioning when said supply voltage is within said subthreshold voltage level of said device.

2. The system of claim 1, wherein said subthreshold data memory contains a write portion and a read portion, wherein said write portion further comprises a memory cell feedback loop that is capable of breaking feedback associated with writing to a memory cell within said data memory, and wherein said read portion further comprises a hierarchical read bit line.

3. The system of claim 2, wherein said memory cell feedback loop further comprises a first feedback inverter, and a memory bit cell, where said memory bit cell further comprises an inverter and a second feedback inverter, wherein said second feedback inverter is capable of being driven when a voltage level below a threshold voltage of said memory bit cell is received, and wherein the first feedback inverter is capable of being driven when writing to said data memory and not driven when not writing to said data memory.

4. The system of claim 2, wherein said hierarchical read bit line further comprises a series of memory cells, a series of inverters, and multiple stages, a first stage of said multiple stages containing a first series of multiplexers, and a second stage of said multiple stages contains a second series of multiplexers.

5. The system of claim 4, wherein said hierarchical read bit line is further defined by a series of input lines, a first input line within said series of input lines connecting a first memory cell, of said series of memory cells, to a first inverter, of said series of inverters, to a first multiplexer, of said first series of multiplexers, and a second input line within said series of input lines connecting a second memory cell, of said series of memory cells, to a second inverter, of said series of inverters, to said first multiplexer, of said first series of multiplexers.

6. The system of claim 4, wherein each multiplexer within said second series of multiplexers is connected to two multiplexers within said first series of multiplexers.

7. The system of claim 4, wherein each of said multiplexers contains an inverter.

8. The system of claim 1, wherein said data memory is fabricated from complementary metal oxide semiconductor logic.

9. The system of claim 2, wherein said read only memory contains a second hierarchical read bit line comprising a series of memory cells, a series of inverters, and multiple stages, a first stage of said multiple stages containing a first series of multiplexers, and a second stage of said multiple stages containing a second series of multiplexers.

10. The system of claim 9, wherein said second hierarchical read bit line is further defined by a series of input lines, a first input line within said series of input lines connecting a first memory cell, of said series of memory cells, to a first inverter, of said series of inverters, to a first multiplexer, of said first series of multiplexers, and a second input line within said series of input lines connecting a second memory cell, of said series of memory cells, to a second inverter, of said series of inverters, to said first multiplexer, of said first series of multiplexers.

11. The system of claim 1, further comprising a data path for performing data calculations required by said device.

12. The system of claim 11, wherein said data path is a butterfly data path, said butterfly data path further comprising a complex valued butterfly for performing complex valued multiplication and complex addition/subtraction, and a backend processing block for converting complex valued Fast Fourier Transform to real valued Fast Fourier Transform.

13. The system of claim 12, wherein said complex valued butterfly is further defined by performing calculations in accordance with the equations X=A+B*W and Y=A−B*W, where A, B, and W are complex inputs to said complex valued butterfly and X and Y are complex outputs to said complex valued butterfly.

14. The system of claim 12, wherein said backend processing block is further defined by performing calculations in accordance with the equations A_{backend}=(A_{I}+B_{I})+j(A_{Q}−B_{Q}) and B_{backend}=(A_{Q}+B_{Q})+j(A_{I}−B_{I}), where A_{I} and A_{Q} represent real and imaginary parts of complex value A and where B_{I} and B_{Q} represent real and imaginary parts of complex value B.

15. The system of claim 1, wherein said control logic is a finite state machine.

16. A wireless microsensor, comprising:
a sensor capable of sensing environmental elements associated with a purpose of said wireless microsensor;
a sensor specific core containing logic that is hard wired and configured to perform a single function associated with said purpose of said wireless microsensor;
a low-end sensor processor capable of performing multiple functions associated with said purpose of said wireless microsensor in accordance with instructions defined by software;
a protocol processor capable of providing functionality associated with providing wireless communication capabilities of said wireless microsensor;
a transceiver capable of enabling wireless communication within said wireless microsensor; and
a subthreshold processor capable of enabling said wireless microsensor to function at a voltage level below a threshold voltage level of said wireless microsensor.

17. The wireless microsensor of claim 16, wherein said subthreshold processor further comprises:
a data memory containing a write portion and a read portion, wherein said write portion further comprises a memory cell feedback loop that is capable of breaking feedback associated with writing to a memory cell within said data memory, and wherein said read portion further comprises a hierarchical read bit line;
control logic; and
a read only memory.

18. The wireless microsensor of claim 16, wherein said memory cell feedback loop further comprises a first feedback inverter, and a memory bit cell, where said memory bit cell further comprises an inverter and a second feedback inverter, wherein said second feedback inverter is capable of being driven when a voltage level below a threshold voltage of said memory bit cell is received, and wherein the first feedback inverter is capable of being driven when writing to said data memory and not driven when not writing to said data memory.

19. The wireless microsensor of claim 16, wherein said hierarchical read bit line further comprises a series of memory cells, a series of inverters, and multiple stages, a first stage of said multiple stages containing a first series of multiplexers, and a second stage of said multiple stages containing a second series of multiplexers.

20. The wireless microsensor of claim 19, wherein said hierarchical read bit line is further defined by a series of input lines, a first input line within said series of input lines connecting a first memory cell, of said series of memory cells, to a first inverter, of said series of inverters, to a first multiplexer, of said first series of multiplexers, and a second input line within said series of input lines connecting a second memory cell, of said series of memory cells, to a second inverter, of said series of inverters, to said first multiplexer, of said first series of multiplexers.

21. The wireless microsensor of claim 19, wherein each multiplexer within said second series of multiplexers is connected to two multiplexers within said first series of multiplexers.

22. The wireless microsensor of claim 19, wherein each of said multiplexers contains an inverter.

23. The wireless microsensor of claim 17, wherein said read only memory contains a second hierarchical read bit line comprising a series of memory cells, a series of inverters, and multiple stages, a first stage of said multiple stages containing a first series of multiplexers, and a second stage of said multiple stages containing a second series of multiplexers.

24. The wireless microsensor of claim 23, wherein said second hierarchical read bit line is further defined by a series of input lines, a first input line within said series of input lines connecting a first memory cell, of said series of memory cells, to a first inverter, of said series of inverters, to a first multiplexer, of said first series of multiplexers, and a second input line within said series of input lines connecting a second memory cell, of said series of memory cells, to a second inverter, of said series of inverters, to said first multiplexer, of said first series of multiplexers.

25. The wireless microsensor of claim 17, further comprising a data path for performing data calculations required by said wireless microsensor.

26. The wireless microsensor of claim 25, wherein said data path is a butterfly data path, said butterfly data path further comprising a complex valued butterfly for performing complex valued multiplication and complex addition/subtraction, and a backend processing block for converting complex valued Fast Fourier Transform to real valued Fast Fourier Transform.

27. The wireless microsensor of claim 26, wherein said complex valued butterfly is further defined by performing calculations in accordance with the equations X=A+B*W and Y=A−B*W, where A, B, and W are complex inputs to said complex valued butterfly and X and Y are complex outputs to said complex valued butterfly.

28. The wireless microsensor of claim 27, wherein said backend processing block is further defined by performing calculations in accordance with the equations A_{backend}=(A_{I}+B_{I})+j(A_{Q}−B_{Q}) and B_{backend}=(A_{Q}+B_{Q})+j(A_{I}−B_{I}), where A_{I} and A_{Q} represent real and imaginary parts of complex value A and where B_{I} and B_{Q} represent real and imaginary parts of complex value B.

29. The wireless microsensor of claim 17, wherein said control logic is a finite state machine.

30. The wireless microsensor of claim 17, wherein said subthreshold processor is located within said sensor specific core, said low-end processor, and said protocol processor.

31. A method of determining an optimal operating point of a device, where said optimal operating point is within a subthreshold voltage level of said device, said method comprising the steps of:
determining switching energy of said device;
determining leakage energy of said device;
combining said switching energy and said leakage energy, resulting in a combined energy;
plotting said combined energy for different supply voltage and/or threshold voltage values, resulting in a contour; and
determining a lowest point on said contour to derive said optimal operating point of said device.

32. The method of claim 31, wherein said step of determining switching energy of said device further comprises using the equation E_{switching}=αNCV²_{DD}, where a is an activity factor, N is an number of clock cycles, C is a switched capacitance of said device, and V_{DD} is said supply voltage.

33. The method of claim 31, wherein said step of determining leakage energy of said device further comprises using the equation
$${E}_{leakage} = {V}_{DD} {I}_{S} exp ( \frac{{V}_{gs} - {V}_{th}}{{nV}_{T}} ) 1 - exp \frac{- {V}_{ds}}{( {V}_{T} )} T ,$$
where I_{S} is a technology dependent scaling parameter, V_{gs} is a gate-to-source voltage, V_{ds} is a drain-to-source voltage, Vₜₕ is said threshold voltage of said device, V_{T} is a thermal voltage, S is a subthreshold slope, and T is a latency of computation.
